(19) United States
(12) Patent Application Publication
(10) Pub. No.: US 2007/0267679 A1
(43) Pub. Date: Nov. 22, 2007

(54) Nonvolatile memory devices including floating gates formed of silicon nano-crystals and methods of manufacturing the same

(75) Inventors: Young-kwan Cha, Yongin-si (KR); Suk-ho Choi, Yongin-si (KR); Kyu-il Han, Yongin-si (KR); Young-soo Park, Yongin-si (KR); Sang-jin Park, Yongin-si (KR); Yong-min Park, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/723,020

(22) Filed: Mar. 15, 2007

(30) Foreign Application Priority Data
May 18, 2006 (KR) 10-2006-0044639

(51) Int. Cl. H01L 29/788; H01L 21/336

(52) U.S. Cl. 257/315; 438/264; 257/E29.3; 257/E21.409

(57) ABSTRACT

A memory device includes a gate stack on a substrate. The gate stack is disposed between a source and a drain. The gate stack includes a tunneling film, storage node, and control oxide film. A thickness of the control oxide film is greater than or equal to about 5 nm and less than or equal to about 30 nm. A method of manufacturing a memory device, including a gate stack on a substrate, wherein the gate stack is disposed between a source and a drain, includes: sequentially forming a tunneling film, a first silicon-rich oxide film, and a control oxide film on the substrate, wherein the first silicon-rich oxide film comprises a SiOₓ film (1.5<x<1.7); converting the first silicon-rich oxide film into a silicon oxide (SiO₂) film comprising silicon nano-crystals; and patterning the control oxide film, the silicon oxide film, and the tunneling film to form the gate stack.

### PRIORITY STATEMENT

This application claims priority from Korean Patent Application No. 10-2006-0044639, filed on May 18, 2006, in the Korean Intellectual Property Office (KIPO), the entire contents of which are incorporated herein by reference.

### BACKGROUND

1. Field

Example embodiments relate to semiconductor memory devices and methods of manufacturing the semiconductor memory devices. Also, example embodiments relate to nonvolatile memory devices including a floating gate (storage node) formed of silicon nano-crystals and methods of manufacturing the nonvolatile memory devices including a floating gate (storage node) formed of silicon nano-crystals.

2. Description of Related Art

Currently, most memory devices may be nonvolatile memory devices that have advantages of existing volatile memory devices, unlike existing flash memory devices. Examples of such nonvolatile memory devices include Phase Change Random Access Memory (PRAM), Magnetic RAM (MRAM), Ferroelectric RAM (FRAM), Resistive RAM (RRAM), and/or Silicon-Oxide-Nitride-Oxide-Silicon (SONOS) memory devices. Also, nonvolatile memory devices using storage nodes formed of nano-crystals may be regarded as next generation memory devices, and may include for example, nonvolatile memory devices including floating gates formed of silicon nano-crystal (Si NC NFGM).

Extensive research has been conducted on Si NC NFGMs, however, Si NC NFGMs formed of manufactured up to now (hereinafter, referred to as related art NFGMs) have narrow memory window, and its characteristics of retention time and endurance cycle may not be adequate for practical use. Therefore, related art NFGMs may not be commercially used as of now.

### SUMMARY

Example embodiments may provide nonvolatile memory devices including a floating gate formed of silicon nano-crystal that can increase memory window and improve one or more operational properties, such as retention time.

Example embodiments also may provide methods of manufacturing the nonvolatile memory device including the floating gate formed of silicon nano-crystal.

According to example embodiments, a memory device includes a gate stack on a substrate disposed between a source and a drain, wherein the gate stack includes a tunneling film, a storage node, and/or a control oxide film. Thickness of the control oxide film may be greater than or equal to about 5 nm and less than or equal to about 30 nm.

Thickness of the tunneling film may be greater than or equal to about 2.5 nm and less than or equal to about 5 nm.

Thickness of the storage node may be greater than or equal to about 10 nm and less than or equal to about 14 nm.

The storage node may be formed of a silicon oxide (SiO₂) film including silicon nano-crystals. Also, the storage node may include a first nano-crystal layer, an intermediate insulating film, and/or a second nano-crystal layer. Thickness of the first nano-crystal layer may be greater than or equal to about 2 nm and less than or equal to about 6 nm. Thickness of the second nano-crystal layer may be greater than or equal to about 2 nm and less than or equal to about 6 nm, respectively.

The intermediate insulating film may be a silicon oxide (SiO₂) film. Thickness of the intermediate insulating film may be greater than or equal to about 3 nm and less than or equal to about 5 nm.

According to example embodiments, methods of manufacturing memory devices, that include a gate stack formed on a substrate and disposed between a source and a drain, include: forming a tunneling film, a first silicon-rich oxide film, and/or a control oxide film sequentially on the substrate, wherein the first silicon-rich oxide film is formed of a SiOₓ film (1.5<x<1.7); converting the first silicon-rich oxide film into a silicon oxide (SiO₂) film including silicon nano-crystals; and patterning the control oxide film, the first silicon oxide film, and/or the tunneling film to form the gate stack. The gate stack may be, for example, laminated on the substrate. The tunneling film, first silicon-rich oxide film, and/or the control oxide film may be, for example, laminated sequentially on the substrate. The control oxide film, the first silicon oxide film, and/or the tunneling film may be, for example, patterned sequentially to form the gate stack.

The first silicon-rich oxide film may be formed, for example, using an ion beam sputtering deposition method.

Thickness of the tunneling film may be greater than or equal to about 2.5 nm and less than or equal to about 5 nm. Thickness of the first silicon-rich oxide film may be greater than or equal to about 10 nm and less than or equal to about 14 nm. Thickness of the control oxide film may be greater than or equal to about 5 nm and less than or equal to about 30 nm.

The converting of the first silicon-rich oxide film may include annealing the first silicon-rich oxide film.

The converting of the first silicon-rich oxide film may be performed before the control oxide film is formed.

The method of manufacturing a memory device may further include forming an intermediate insulating film and a second silicon-rich (SiOₓ) film (1.5<x<1.7) sequentially on the first silicon-rich oxide film before the control oxide film is formed, wherein the converting of the first silicon-rich oxide film may include converting the second silicon-rich oxide film into a silicon oxide film including silicon nano- crystals. Thickness of the first silicon-rich (SiO₂) film may be greater than or equal to about 2 nm and less than or equal to about 6 nm. Thickness of the second silicon-rich (SiOₓ) film may be greater than or equal to about 2 nm and less than or equal to about 6 nm. The second silicon-rich (SiOₓ) film may be formed, for example, using an ion beam sputtering deposition method. Thickness of the intermediate insulating film may be greater than or equal to about 3 nm and less than or equal to about 5 nm.

The converting the first silicon-rich oxide film may be performed after the gate stack is formed.

### BRIEF DESCRIPTION OF THE DRAWINGS

The above and/or other aspects and advantages will become more apparent and more readily appreciated from the following detailed description of example embodiments taken in conjunction with the accompanying drawings, in which:

FIGS. 1 through 4 are cross-sectional views sequentially illustrating methods of manufacturing nonvolatile memory devices including a floating gate formed of a single silicon nano-crystal layer, according to an example embodiment;

FIG. 5 is a cross-sectional view of a gate stack of a nonvolatile memory device including two silicon nano-crystal layers as storage nodes, according to an example embodiment;

FIGS. 6 through 8 are graphs illustrating a characteristic of retention time of a nonvolatile memory device including a single silicon nano-crystal layer, according to an example embodiment; and

FIGS. 9 through 14 are graphs illustrating a characteristic of retention time of a nonvolatile memory device including two silicon nano-crystal layers, according to an example embodiment.

### DETAILED DESCRIPTION OF EXAMPLE EMBODIMENTS

Example embodiments will now be described more fully with reference to the accompanying drawings. Embodiments may, however, be embodied in many different forms and should not be construed as being limited to the example embodiments set forth herein; rather, these embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to,” or “coupled to” another component, it may be directly on, connected to, or coupled to the other component or intervening components may be present. In contrast, when a component is referred to as being “directly on,” “directly connected to,” or “directly coupled to” another component, there are no intervening components present. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the example embodiments.

Spatially relative terms, such as “beneath,” “below,” “lower,” “above,” “upper,” and the like may be used herein for ease of description to describe one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to the like components throughout.

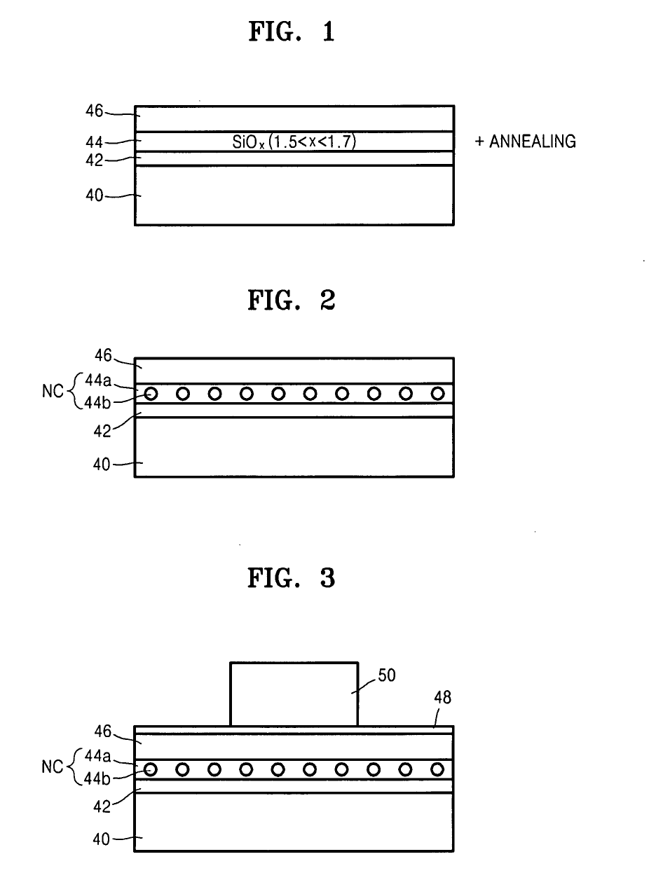

FIGS. 1 through 4 are cross-sectional views sequentially illustrating methods of manufacturing nonvolatile memory devices including a floating gate formed of a single silicon nano-crystal layer, according to an example embodiment.

Referring to FIG. 1, a tunneling film 42, a silicon-rich oxide film 44, and/or a control oxide film 46 may be sequentially formed on a substrate 40. Thickness of the tunneling film 42 may be greater than or equal to about 2.5 nm and less than or equal to about 5 nm (i.e., 3 nm). The tunneling film 42 may be formed of a silicon oxide (SiO₂) film. Thickness of the silicon-rich oxide film 44 may be greater than or equal to about 10 nm and less than or equal to about 14 nm (i.e., 12 nm) and may be formed of a SiOₓ film (1.5<x<1.7). The silicon-rich oxide film 44 may be formed, for example, using an ion beam sputtering deposition method that may provide an ultra high vacuum deposition condition to reduce defect density of the silicon-rich oxide film 44 and may enable low-temperature growth of the silicon-rich oxide film 44. Thickness of the control oxide film 46 may be greater than or equal to about 5 nm and less than or equal to about 30 nm. The control oxide film 46 may be formed of the same material as the tunneling film 42. However, the control oxide film 46 may be formed of one or more different material(s) from the tunneling film 42.

After the tunneling film 42, the silicon-rich oxide film 44, and/or the control oxide film 46 are formed, the laminated resultant may be annealed at temperature(s)—that may or may not be predetermined-for duration(s)—that may or may not be predetermined. For example, when both the tunneling film 42 and the control oxide film 46 include a SiO₂ film and the silicon-rich oxide film 44 includes a SiOₓ (1.5<x<1.7) film, the temperature may be about 1100° C. and the duration may be about 20 minutes.

In addition or in the alternative, the silicon-rich oxide film 44 may include an amorphous silicon film.

While silicon nano-crystals 44b may be formed in the silicon-rich oxide film 44 by the annealing, a remaining portion of the silicon-rich oxide film 44 may be converted into a general silicon oxide (SiO₂) film 44a, as illustrated in FIG. 2. Therefore, the silicon-rich oxide film 44 that undergoes the annealing process may be converted into the silicon oxide (SiO₂) film 44a, including silicon nano-crystals 44b. Hereinafter, the silicon oxide (SiO₂) film 44a, including the silicon nano-crystals 44b, may be referred to as a nano-crystal layer NC. The nano-crystal layer NC may be used as a floating gate and electrons may be trapped in the silicon nano-crystals 44b. The nano-crystal layer NC may indicate a layer formed of the silicon nano-crystals 44b only.

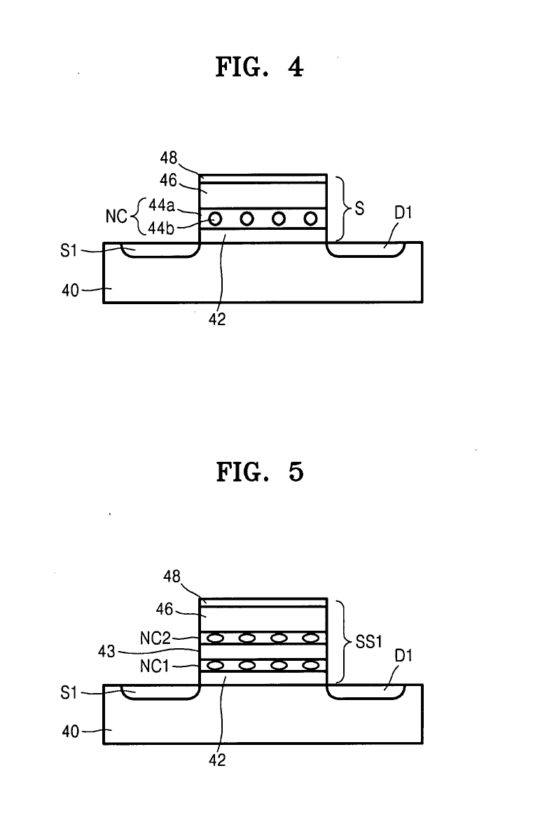

Referring to FIG, 3, when the annealing process is completed, a gate electrode layer 48 may be formed on the control oxide film 46. The gate electrode layer 48 may be used as a control gate. The gate electrode layer 48 may be formed of aluminum, however, the gate electrode 48 also may be formed of other material(s). A photosensitive pattern 50 may be formed on the gate electrode layer 48. The photosensitive pattern 50 may define a predetermined region of the gate electrode layer 48. The layers formed on the substrate 40 may be, for example, anisotropically etched until the substrate 40 is exposed using the photosensitive pattern 50 as an etching mask. Then, the photosensitive pattern 50 may be removed. As a result, a gate stack S may be formed on the substrate 40, as illustrated in FIG. 4. When the gate stack S is formed, conductive impurities may be implanted in the substrate 40 to form first and second impurities regions S1 and D1, respectively, disposed at left and right sides of the gate stack S formed on the substrate 40. Here, the conductive impurities may be impurities having an opposite conductivity to that of the substrate 40 (i.e. n-type impurities). One of the first and second impurities regions S1 and D1 may be a source region and the other may be a drain region.

In addition or in the alternative, the annealing process for the silicon-rich oxide film 44 may be performed after the gate stack S of FIG. 4 is formed. In addition, when the material used to form the gate electrode layer 48 may endure the annealing process, the annealing process of FIG. 1 may be performed after the gate electrode layer 48 is formed on the control oxide film 46. Moreover, the annealing process of FIG. 1 may be performed after the silicon-rich oxide film 44 is formed and before the control oxide film 46 is formed.

FIG. 5 is a cross-sectional view of a gate stack of a nonvolatile memory device including two silicon nano-crystal layers as storage nodes, according to an example embodiment.

Referring to FIG. 5, the gate stack SS1 that may be formed on a substrate 40 may be disposed between first and second impurities regions S1 and D1 and may include a tunneling film 42, a first nano-crystal layer NC1, an intermediate insulating film 43, a second nano-crystal layer NC2, a control oxide film 46, and/or a gate electrode layer 48 that may be sequentially formed. Thickness of the first nano-crystal layer NC1 may be greater than or equal to about 2 nm and less than or equal to about 6 nm. Thickness of the second nano-crystal layer NC2 may be greater than or equal to about 2 nm and less than or equal to about 6 nm. First nano-crystal layer NC1 and/or second nano-crystal layer NC2 may be formed of the same material as the nano-crystal layer NC of FIG. 4. On the other hand, first nano-crystal layer NC1 and/or second nano-crystal layer NC2 may be formed of one or more different materials than the nano-crystal layer NC of FIG. 4. The intermediate insulating film 43 may be formed of a silicon oxide (SiO₂) film. Thickness of the silicon oxide (SiO₂) film may be greater than or equal to about 3 nm and less than or equal to about 5 nm (i.e., 4 nm).

The method of manufacturing the gate stack SS1 may be the same as the method of manufacturing the gate stack S illustrated in FIGS. 1 through 4. However, since the gate stack SS1 of FIG. 5 includes two nano-crystal layers NC1 and NC2, the sequence and number of the annealing process(es) may differ.

For example, the annealing process to form the first and second nano-crystal layers NC1 and NC2 may be performed after first and second silicon-rich oxide films (not illustrated), that may be converted into the first and second nano-crystal layers NC1 and NC2 later through the annealing process, are formed in the process of manufacturing the gate stack SS1 of FIG. 5.

In addition, the annealing process to form the first and second nano-crystal layers NC1 and NC2 may include first and second annealing processes. Here, the first annealing process may be performed after the first silicon-rich oxide film is formed and before the second silicon-rich oxide film is formed, or before the intermediate insulating film 43 is formed. The second annealing process may be performed after the second silicon-rich oxide film is formed. The temperature(s) and/or duration(s) to perform the first and second annealing processes may be the same as or different from each other.

Hereinafter, an operational characteristic of a nonvolatile memory device including a floating gate formed of silicon nano-crystals according to an example embodiment is described more fully.

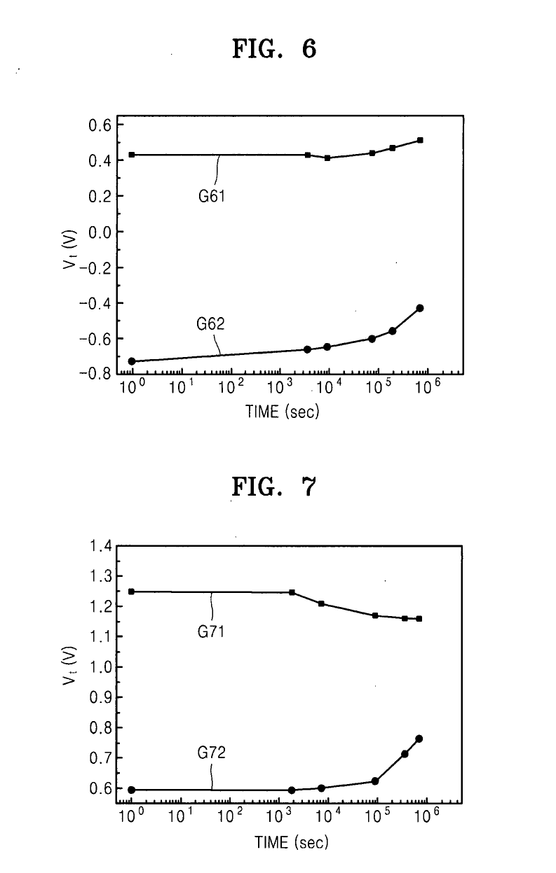

FIGS. 6 through 8 are graphs illustrating a characteristic of retention time of a nonvolatile memory device including a single silicon nano-crystal layer, according to an example embodiment. The single silicon nano-crystal layer NC may be a storage node included in the gate stack S, as illustrated in FIG. 4.

Referring to FIGS. 6 through 8, a characteristic of retention time may be measured at a temperature above room temperature, for example, 85° C., and a characteristic of retention time illustrated in FIGS. 9 through 11 may be measured at this temperature.

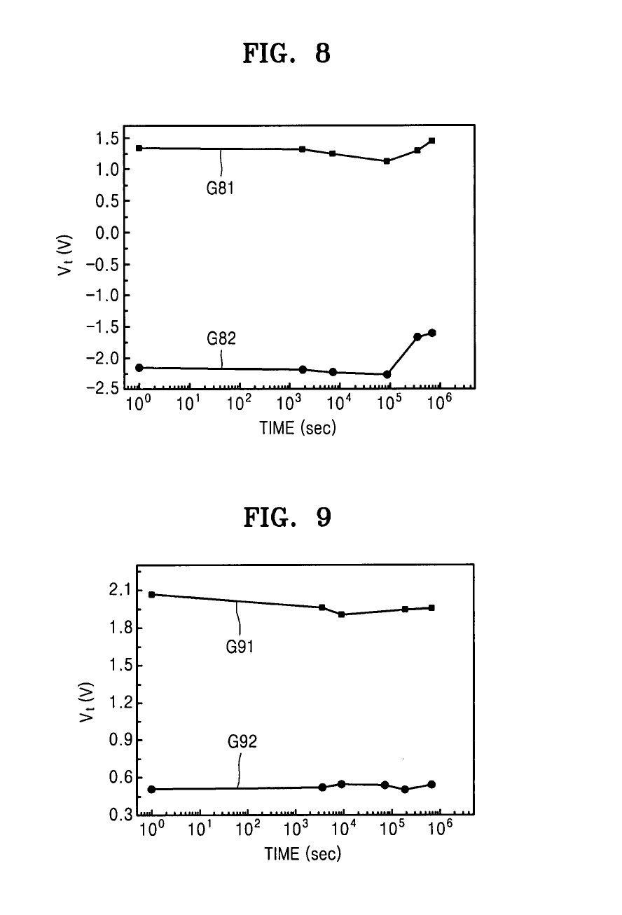

FIG. 6 shows a characteristic of retention time when the control oxide film 46, the nano-crystal layer NC, and the tunneling film 42 included in the gate stack S of FIG. 4 have thicknesses of 5 nm, 12 nm, and 3 nm, respectively. FIG. 7 shows a characteristic of retention time when the control oxide film 46, the nano-crystal layer NC, and the tunneling film 42 included in the gate stack S of FIG. 4 have thicknesses of 15 nm, 12 nm, and 3 nm, respectively. FIG. 8 shows a characteristic of retention time when the control oxide film 46, the nano-crystal layer NC, and the tunneling film 42 included in the gate stack S of FIG. 4 have thicknesses of 30 nm, 12 nm, and 3 nm, respectively. That is, only the thickness of the control oxide film 46 is changed in FIGS. 6 through 8.

In FIGS. 6 through 8, first plots G61, G71, and G81 show changes of threshold voltages with respect to the time when data is recorded, that is, after the NFGM is programmed, and second plots G62, G72, and G82 show changes of threshold voltages with respect to the time when the recorded data is removed.

Comparing FIGS. 6 through 8, when the thicknesses of the nano-crystal layer NC and the tunneling film 42 are fixed at 12 nm and 3 nm, respectively, and only the thickness of the control oxide film 46 is changed, the characteristic of retention time is quite similar. That is, the difference between threshold voltages after data is recorded (first plots G61, G71, and G81 of each graph) and threshold voltages after the recorded data is removed (second plots G62, G72, and G82 of each graph) is reduced after 10⁵seconds elapses, however, the difference is higher than 0.3 V even at 106 seconds. Since the difference between two threshold voltages in a related art NFGM is only 0.2 V already at 10⁴ seconds, a characteristic of retention time of the NFGM of the example embodiment is improved.

The results in the graphs of FIGS. 6 through 8 show that the difference between the threshold voltages after the data is recorded and the threshold voltages after the recorded data is removed may be larger than in a related art NFGM and/or the reduction rate of the difference may be lower than a related art NFGM. Therefore, a memory window in the NFGM of the example embodiment is broader than a related art memory window.

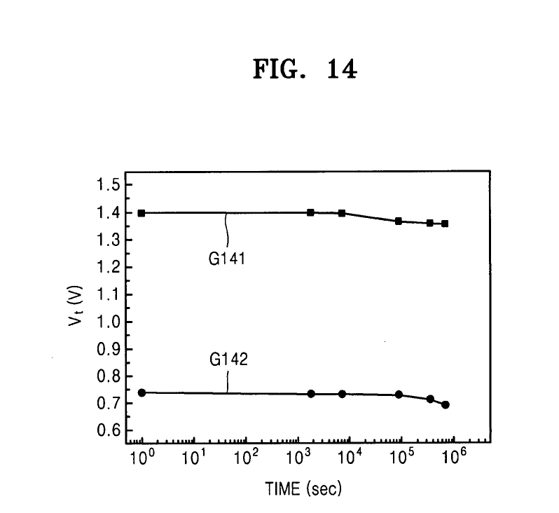

FIGS. 9 through 14 are graphs illustrating a characteristic of retention time of a nonvolatile memory device including two silicon nano-crystal layers, according to an example embodiment. The two silicon nano-crystal layers NC1 and NC2 may be storage nodes included in the gate stack SS1, as illustrated in FIG. 5.

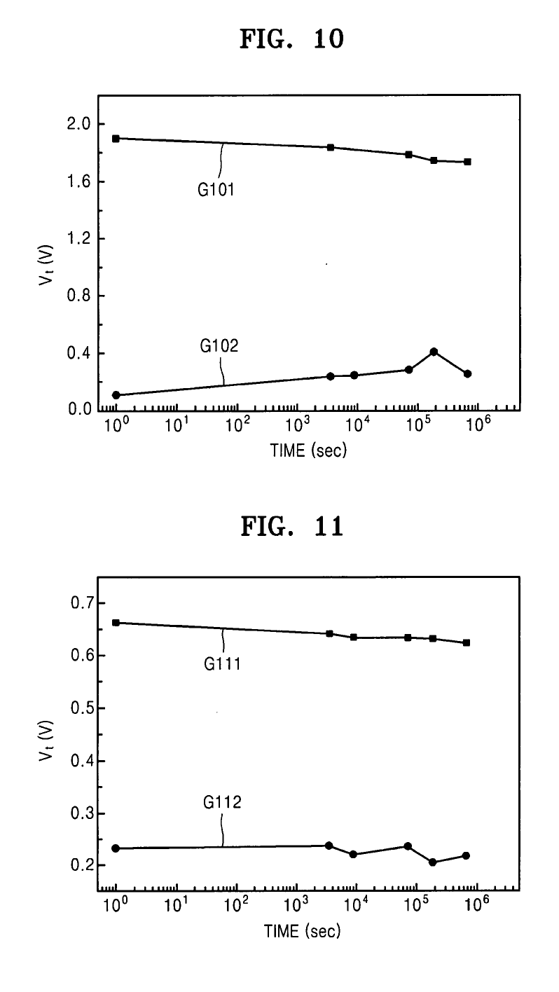

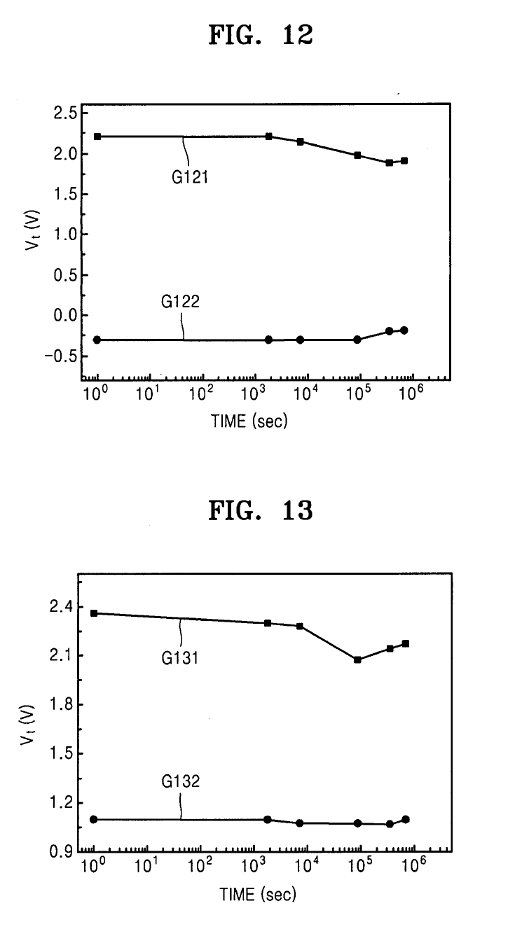

FIG. 9 shows a characteristic of retention time when the control oxide film 46, the second nano-crystal layer NC2, the intermediate insulating film 43, the first nano-crystal layer NC1, and the tunneling film 42 included in the gate stack SS1 of FIG. 5 have thicknesses of 5 nm, 4 nm, 4 nm, 4 nm, and 3 nm, respectively. FIG. 10 shows a characteristic of retention time when the control oxide film 46, the second nano-crystal layer NC2, the intermediate insulating film 43, the first nano-crystal layer NC1, and the tunneling film 42 included in the gate stack SS1 of FIG. 5 have thicknesses of 5 nm, 6 nm, 4 nm, 2 nm, and 3 nm, respectively. In addition, FIGS. 12 through 14 show a characteristic of retention time when only the thickness of the control oxide film 46 is changed from 5 nm to 15 nm and the second nano-crystal layer NC2, the intermediate insulating film 43, the first nano-crystal layer NC1, and the tunneling film 42 are the same as in FIGS. 9 through 11, respectively. FIG. 11 shows a characteristic of retention time when the control oxide film 46, the second nano-crystal layer NC2, the intermediate insulating film 43, the first nano-crystal layer NC1, and the tunneling film 42 included in the gate stack SS1 of FIG. 5 have thicknesses of 5 nm, 2 nm, 4 nm, 6 nm, and 3 nm, respectively.

In FIGS. 9 through 14, first plots G91, G101, G11, G121, G131, and G141 show changes of threshold voltages with respect to the time when data is recorded, that is, after the NFGM of FIG. 5 is programmed, and second plots G92, G102, G112, G122, G132, and G142 show changes of threshold voltages with respect to the time when the recorded data is removed.

Referring to FIGS. 9 through 14, the difference between threshold voltages after data is recorded and threshold voltages after the recorded data is removed may remain as high or almost as high as in the initial stage even after 106 seconds elapses. As a result, a characteristic of retention time of the NFGM illustrated in FIG. 5 may have little relationship to the thickness of the control oxide film 46.

On the other hand, a characteristic of retention time illustrated in FIGS. 6 through 8 is gradually reduced after 10⁵ seconds elapses, while a characteristic of retention time illustrated in FIGS. 9 through 11 and/or a characteristic of retention time illustrated in FIGS. 12 through 14 is almost not changed, showing a gentle and flat slope even after 10⁵ seconds elapses.

Subsequently, a characteristic of retention time of the NFGM according to an example embodiment may be related to the number of storage nodes included in the gate stack, that is, the number of nano-crystal layers. A characteristic of retention time may be better in a single nano-crystal layer than a related art NFGM, however, it may be better yet in two single nano-crystal layers.

On the other hand, when the thickness of one of the second nano-crystal layer NC2, the intermediate insulating film 43, and/or the first nano-crystal layer NC1 is changed, the same result as in FIGS. 9 through 14 may be obtained.

As described above, the NFGM of the example embodiment includes a tunneling film, a nano-crystal layer, and/or a control oxide film having thickness(es) that may or may not be predetermined. When there are a plurality of nano-crystal layers, one or more intermediate insulating films having a thickness-that may or may not be predetermined-may be interposed between the nano-crystal layers.

As such, when the NFGM includes a tunneling film, a nano-crystal layer, and a control oxide film having thicknesses-that may or may not be predetermined-as well as a plurality of nano-crystal layers including intermediate insulating films therebetween, a characteristic of retention time of the NFGM may be improved as illustrated in FIGS. 6 through 14 and thus, the memory window may be also broadened.

A gate stack may include three or more nano-crystal layers and/or one or more amorphous silicon films, in addition to or instead of one or more silicon-rich oxide films. The tunneling film, the control oxide film, and/or the intermediate insulating film may be formed of other oxide films or non-oxide films, in addition to silicon oxide (SiO₂) films. In addition, the nano-crystal layers may be formed of other materials instead of silicon.

While example embodiments have been particularly shown and described, it will be understood by those of ordinary skill in the art that various changes in form and details may be made therein without departing from the spirit and scope of the present invention as defined by the following claims.

What is claimed is:

1. A memory device, comprising:
a gate stack on a substrate;
wherein the gate stack is disposed between a source and a drain,
wherein the gate stack comprises:
a tunneling film;
a storage node; and
a control oxide film; and
wherein a thickness of the control oxide film is greater than or equal to about 5 nm and less than or equal to about 30 nm.

2. The memory device of claim 1, wherein a thickness of the tunneling film is greater or equal to about 2.5 nm and less than or equal to about 5 nm.

3. The memory device of claim 1, wherein a thickness of the storage node is greater than or equal to about 10 nm and less than or equal to about 14 nm.

4. The memory device of claim 1, wherein the storage node is formed of a silicon oxide (SiO₂) film comprising silicon nano-crystals.

5. The memory device of claim 1, wherein the storage node comprises:
a first nano-crystal layer;
an intermediate insulating film; and
a second nano-crystal layer.

6. The memory device of claim 5, wherein a thickness of the first nano-crystal layer is greater than or equal to about 2 nm and less than or equal to about 6 nm, and
wherein a thickness of the second nano-crystal layer is greater than or equal to about 2 nm and less than or equal to about 6 nm.

7. The memory device of claim 5, wherein the intermediate insulating film is a silicon oxide (SiO₂) film, and
wherein a thickness of the intermediate insulating film is greater than or equal to about 3 nm and less than or equal to about 5 nm.

8. The memory device of claim 2, wherein a thickness of the storage node is greater than or equal to about 10 nm and less than or equal to about 14 nm.

9. A method of manufacturing a memory device comprising a gate stack on a substrate, wherein the gate stack is disposed between a source and a drain, the method comprising:
sequentially forming a tunneling film, a first silicon-rich oxide film, and a control oxide film on the substrate, wherein the first silicon-rich oxide film comprises a SiOₓ film (1.5<x<1.7);
converting the first silicon-rich oxide film into a silicon oxide (SiO₂) film comprising silicon nano-crystals; and
patterning the control oxide film, the silicon oxide film, and the tunneling film to form the gate stack.

10. The method of claim 9, wherein the first silicon-rich oxide film is formed using an ion beam sputtering deposition method.

11. The method of claim 9, wherein a thickness of the tunneling film is greater than or equal to about 2.5 nm and less than or equal to about 5 nm.

12. The method of claim 9, wherein a thickness of the first silicon-rich oxide film is greater than or equal to about 10 nm and less than or equal to about 14 nm.

13. The method of claim 9, wherein a thickness of the control oxide film is greater than or equal to about 5 nm and less than or equal to about 30 nm.

14. The method of claim 9, wherein the converting the first silicon-rich oxide film comprises annealing the first silicon-rich oxide film.

15. The method of claim 9, wherein the converting the first silicon-rich oxide film is performed before the control oxide film is formed.

16. A method of manufacturing a memory device comprising a gate stack on a substrate, wherein the gate stack is disposed between a source and a drain, the method comprising:
sequentially forming a tunneling film, a first silicon-rich oxide film, an intermediate insulating film, a second silicon-rich oxide film, and a control oxide film on the substrate, wherein the first silicon-rich oxide film comprises a SiOₓ film (1.5<x<1.7) and wherein the second silicon-rich oxide film comprises a SiO_{y} film (1.5<y<1.7);
converting the second silicon-rich oxide film into a second silicon oxide (SiO₂) film comprising silicon nano-crystals; and
patterning the control oxide film, the first silicon-rich oxide film, the intermediate insulating film, the second silicon oxide (SiO₂) film, and the tunneling film to form the gate stack.

17. The method of claim 16, wherein x=y.

18. The method of claim 16, further comprising:
converting the first silicon-rich oxide film into a first silicon oxide (SiO₂) film comprising silicon nano-crystals.

19. The method of claim 16, wherein a thickness of the first silicon-rich oxide film is greater than or equal to about 2 nm and less than or equal to about 6 nm, and
wherein a thickness of the second silicon oxide (SiO₂) film is greater than or equal to about 2 nm and less than or equal to about 6 nm.

20. The method of claim 16, wherein the first silicon-rich oxide film is formed using an ion beam sputtering deposition method.

21. The method of claim 16, wherein the second silicon-rich oxide film is formed using an ion beam sputtering deposition method.

22. The method of claim 16, wherein a thickness of the intermediate insulating film is greater than or equal to about 3 nm and less than or equal to about 5 nm.

23. A method of manufacturing a memory device comprising a gate stack on a substrate, wherein the gate stack is disposed between a source and a drain, the method comprising:
sequentially forming a tunneling film, a first silicon-rich oxide film, an intermediate insulating film, a second silicon-rich oxide film, and a control oxide film on the substrate, wherein the first silicon-rich oxide film comprises a SiOₓ film (1.5<x<1.7) and wherein the second silicon-rich oxide film comprises a SiO_{y} film (1.5<y<1.7);
converting the first silicon-rich oxide film into a first silicon oxide (SiO₂) film comprising silicon nano-crystals; and
patterning the control oxide film, the first silicon oxide (SiO₂) film, the intermediate insulating film, the second silicon-rich oxide film, and the tunneling film to form the gate stack.

24. The method of claim 23, wherein x=y.

25. The method of claim 23, further comprising:
converting the second silicon-rich oxide film into a second silicon oxide (SiO₂) film comprising silicon nano-crystals.

26. The method of claim 23, wherein a thickness of the first silicon oxide (SiO₂) film is greater than or equal to about 2 nm and less than or equal to about 6 nm, and
wherein a thickness of the second silicon-rich oxide film is greater than or equal to about 2 nm and less than or equal to about 6 nm.

27. The method of claim 23, wherein the first silicon-rich oxide film is formed using an ion beam sputtering deposition method.

28. The method of claim 23, wherein the second silicon-rich oxide film is formed using an ion beam sputtering deposition method.

29. The method of claim 23, wherein a thickness of the intermediate insulating film is greater than or equal to about 3 nm and less than or equal to about 5 nm.

30. A method of manufacturing a memory device comprising a gate stack on a substrate, wherein the gate stack is disposed between a source and a drain, the method comprising:
sequentially forming a tunneling film, a first silicon-rich oxide film, an intermediate insulating film, a second silicon-rich oxide film, and a control oxide film on the substrate, wherein the first silicon-rich oxide film comprises a SiOₓ film (1.5<x<1.7) and wherein the second silicon-rich oxide film comprises a SiO_{y} film (1.5<y<1.7);
converting the first silicon-rich oxide film into a first silicon oxide (SiO₂) film comprising silicon nano-crystals;
converting the second silicon-rich oxide film into a second silicon oxide (SiO₂) film comprising silicon nano-crystals; and
patterning the control oxide film, the first silicon oxide (SiO₂) film, the intermediate insulating film, the second silicon oxide (SiO₂) film, and the tunneling film to form the gate stack.

31. The method of claim 30, wherein x=y.

32. The method of claim 30, wherein the converting the first silicon-rich oxide film is performed after the tunneling film, the first silicon-rich oxide film, and the control oxide film are sequentially formed on the substrate.
